(19) United States
(12) Patent Application Publication
(10) Pub. No.: US 2026/0049411 A1
(43) Pub. Date: Feb. 19, 2026

(54) METHOD FOR CONTROLLED GRADED MATERIALS/ALLOYS IN MOLECULAR BEAM EPITAXY AND CHEMICAL VAPOR DEPOSITION TYPE SYSTEMS

(71) Applicants: Calbi J. Gunder, Fayetteville, AR (US); Emmanuel Simiyu Wangila, Fayetteville, AR (US); Mohammad Zamani-Alavijeh, Farmington, AR (US)

(72) Inventors: Calbi J. Gunder, Fayetteville, AR (US); Emmanuel Simiyu Wangila, Fayetteville, AR (US); Mohammad Zamani-Alavijeh, Farmington, AR (US)

(21) Appl. No.: 19/296,875

(22) Filed: Aug. 11, 2025

Related U.S. Application Data
(60) Provisional application No. 63/682,484, filed on Aug. 13, 2024.

(51) Int. Cl. C30B 23/00; C30B 23/02; C30B 25/16; C30B 29/52

(52) U.S. Cl. CPC C30B 23/002; C30B 23/025; C30B 25/165; C30B 29/52

(57) ABSTRACT

A method for growing a linearly graded germanium-tin film using molecular beam epitaxy (MBE) includes providing a substrate in a molecular beam epitaxy (MBE) chamber; establishing a constant germanium beam equivalent pressure (BEP); applying a logarithmic-based algorithm to dynamically control a tin (Sn) effusion cell temperature to achieve a linear increase in tin (Sn) beam equivalent pressure (BEP) over time; and dynamically adjusting the tin (Sn) effusion cell temperature for growing a linear graded germanium-tin (Ge1-xSnx) film having a linear tin (Sn) composition gradient. The methodology applies to any element or molecule delivered via thermal evaporation, electron-beam evaporation, or vapor-phase methods. For gaseous precursors in CVD systems, flow may be modulated using mass flow controllers or valve adjustments. The approach enables growth of various materials/alloys on substrates including germanium, silicon, sapphire, indium arsenide, indium gallium arsenide, and silicon carbide to name a few.

### CROSS-REFERENCE TO RELATED APPLICATIONS

The present application claims benefit of U.S. Provisional Application No. 63/682,484, filed Aug. 13, 2024; which is incorporated herein in its entirety and referenced thereto.

### FIELD OF THE INVENTION

The present invention relates generally to the field of alloy/material growth, semiconductor fabrication, and in particular, relates to a method for the controlled growth of any thermally evaporated elements/molecules into linearly graded alloys/material films using molecular beam epitaxy. In this specific example, linearly graded germanium-tin films were grown using this method within a molecular beam epitaxy system.

### DESCRIPTION OF THE PRIOR ART

The development of germanium-tin (GeSn) alloy films represents an advancement in semiconductor technology, such as in the development of optoelectronic devices. This is because; the GeSn materials offer unique properties such as tunable bandgaps, high carrier mobility, and compatibility with existing silicon manufacturing processes. The ability to precisely control and reproduce the growth of GeSn enables device performance in applications, including but not limited to, infrared sensors, high-efficiency photodetectors, and laser systems.

Typically, GeSn growth is performed through methods such as Molecular Beam Epitaxy (MBE) and Chemical Vapor Deposition (CVD). The ability to grow GeSn films with precision using molecular beam epitaxy (MBE) plays an important role in advancing research in the GeSn/SiGeSn domain. This is because; MBE allows for finely tuned growth conditions that are essential when engineering GeSn into a direct bandgap material. When alloying GeSn into a direct bandgap material, it is important that factors such as the strain state of the film, the amount of tin (Sn) incorporation, and the degree of short-range ordering within the GeSn lattice structure should be considered. The above factors impact the material's electronic properties and therefore need to be optimized to achieve the performance specifications of the optoelectronic devices.

In today's era of Artificial Intelligence (AI) driven innovation, precise material engineering is required for developing cutting-edge technologies. Algorithm-guided growth strategies are being applied to GeSn film fabrication. For instance, MBE's atomic-layer control enables the ability to precisely adjust composition, minimize defect densities, and maximize Sn composition. This is achieved by controlling material features such as in-plane and out-of-plane strain, composition, and short-range ordering of the resultant bandgap of GeSn. This level of control can enhance the material and also allows the way to be paved for AI systems to automate the experimental process into modifying the behavior of these semiconductor materials and thus their corresponding characteristics in the optoelectronic devices that are produced.

Several methods for forming Ge and/or GeSn have been disclosed in the past. One such example is disclosed in a U.S. Publication No. 20140053894, entitled “GRADED GeSn ON SILICON” (“the '894 Publication”). The '894 Publication discloses a method of fabricating a solar cell on a silicon substrate includes providing a crystalline silicon substrate, selecting a grading profile, epitaxially growing a template on the silicon substrate including a single crystal GeSn layer using the grading profile to grade Sn through the layer. The single crystal GeSn layer has a thickness in a range of approximately 3 μm to approximately 5 μm. At least two layers of high band gap material are epitaxially and sequentially grown on the template to form at least three junctions. The grading profile starts with the Sn at or near zero with the Ge at zero, the percentage of Sn varies to a maximum mid-area, and reduces the percentage of Sn to zero adjacent an upper surface.

Another example is disclosed in a U.S. Publication No. 20210296524, entitled “SiGeSn VIRTUAL SUBSTRATE FORMED BY MOLECULAR BEAM EPITAXY ON A Si SUBSTRATE FOR THE STRAINED GROWTH OF GeSn” (“the '524 Publication”). The '524 Publication discloses a method of growing fully relaxed SiGeSn buffer layers on Si substrates to produce virtual substrates for the epitaxial growth of high quality GeSn films suitable for high performance infrared (IR) optoelectronic device technology directly integrated on silicon. Growing the SiGeSn virtual substrate uses a precisely decreasing growth temperature and Si flux and a precisely increasing Ge and Sn flux. The virtual substrates may have a slightly larger lattice constant than that of the target GeSn alloy to impose a precise degree of tensile strain resulting in a direct band gap for the target GeSn alloy.

Yet another example is disclosed by A. Fisher et al. in “Molecular Beam Epitaxy Growth of SiGeSn Alloys”, in Molecular Beam Epitaxy: Elsevier, 2018, pp 55-71.

Although the above discussed disclosures are useful, they still have problems and present incomplete solutions. For example, the existing methods present a challenge in transforming Germanium (Ge) into a direct bandgap material by alloying it with Tin (Sn) for applications in lasers and infrared detectors. Further, alloying using existing methods, particularly with 6-11% Sn, often result in material defects, Tin segregation, and issues with lattice mismatch. These issues degrade the quality of GeSn films, hindering optical performance.

Therefore, there is a need in the art to provide an improved method that employs a logarithmic equation to refine the alloying of Tin (Sn) into Germanium (Ge), allowing more control over the alloying process, significantly reducing defect propagation and thus vastly improving the quality of GeSn films.

### SUMMARY OF THE INVENTION

It is an object of the present invention to provide a method for growing linearly graded alloys/materials demonstrated with the growths of germanium-tin (GeSn) films using molecular beam epitaxy (MBE).

It is another object of the present invention to provide a logarithmic-based algorithm to dynamically adjust a tin (Sn) effusion cell temperature to ensure a linear increase in tin (Sn) beam equivalent pressure (BEP).

It is another object of the present invention to minimize strain-related defects through controlled linear grading that reduces abrupt strain changes and enhances overall film quality.

In order to achieve one or more objects, the present invention provides a method for growing a linearly graded germanium-tin films using a logarithmic-based algorithm. The method comprises: (a) providing a substrate in a molecular beam epitaxy (MBE) chamber, (b) establishing a constant germanium beam equivalent pressure (BEP), (c) applying a logarithmic-based algorithm to dynamically control a tin (Sn) effusion cell temperature to achieve a linear increase in tin (Sn) beam equivalent pressure (BEP) over time, and (d) dynamically adjusting said tin (Sn) effusion cell temperature for growing a linear graded germanium-tin (Ge₁₋ₓSnₓ) film having a linear tin (Sn) composition gradient based on said logarithmic-based algorithm.

In the prior art, MBE growths were not able to create linear compositional gradients due to the fact that the relationship between the effusion cell temperature and beam equivalent pressure follows an exponential function. This exponential relationship between BEP and effusion cell temperature produces uncontrolled exponential compositional gradients when using the typical effusion cell temperature control means of ramping at a linear rate. This lack of control and uncertainty in compositional ratios can lead to a reduction in the quality and precision of graded semiconductor structures. The presently disclosed method addresses the discussed limitation by implementing a logarithmic-based algorithm. The logarithmic-based algorithm dynamically adjusts the tin effusion cell temperature utilizes an equation:

$${T}_{Sn} = \frac{- Δ {H}_{e}}{R ln ( \frac{at + b}{{P}_{0}} )}$$

In this equation, T_{Sn} represents said tin (Sn) effusion cell temperature, R represents a gas constant, ΔHₑ represents a molar heat of evaporation, and P_{O} represents a constant of integration, t represents growth time, α represents a rate of BEP change across time, and b represents an offset variable that sets the starting BEP. The logarithmic-based algorithm ensures that tin BEP increases linearly over time, which results in accurate linear compositional gradients in the grown GeSn film.

In one advantageous feature of the present invention, the method linearizes the change in flux or equivalent BEP from thermally evaporated elements via effusion cells. This ensures the germanium-tin film growth corresponds to a linear change in tin composition across Ge₁₋ₓSnₓ gradients. The method utilizes the linear gradient of Ge₁₋ₓSnₓ structures and allows for the manipulation of the alloying profile into any type of elemental gradient distribution by breaking the grading profile into smaller linear segments with different grading rates.

In another advantageous feature of the present invention, the method allows GeSn alloying to explore the most effective method for distributing Sn across specific thicknesses, aiming to achieve a direct bandgap material tailored to a specific wavelength of interest. The versatility extends beyond gradient growth, as the method can also be employed for selecting a particular composition or stepped composition structures. The method also enables the identification and utilization of the role of strain gradient and strain energy to achieve a higher Sn content without dislocations. For example, the strain gradient can determine the allowed Sn content per unit length during growth, while the accumulated strain energy can determine the limiting Sn content before relaxation by dislocations. The method can be used to create a linear gradient of any element/molecules without deviating from the scope of the present invention.

A further advantage is in the production of high-quality GeSn with a Sn composition based on the desired specifications. The method allows precision of Sn composition in the GeSn alloy, as it uses GeSn based gradients to get to the required composition while maintaining high-quality films. This allows manufactures to either growth on top of the film or use other tools/methods to grow to the final desired composition with thicknesses desirable for devices. For example, the method can be used in fabrication of near and mid-infrared detectors, lasers, waveguide, microwave photonic devices, and electronic devices like channels in transistors, and terahertz devices to name a few.

These and other objects of the present subject matter will be apparent from review of the following specification and the accompanying drawings.

### BRIEF DESCRIPTION OF THE DRAWINGS

FIG. 1 illustrates the general calibration method and considerations for growing a linear gradient alloy/material.

FIG. 2 illustrates a method for molecular beam epitaxy (MBE) growth of linearly graded germanium-tin (GeSn) films using a logarithmic-based algorithm, in accordance with one embodiment of the present invention.

FIG. 3 illustrates a semiconductor structure comprising GaAs (001) substrate, a GaAs buffer layer, and a GeSn film, in accordance with one embodiment of the present invention.

FIG. 4 illustrates a plot illustrating the relationship between beam equivalent pressure (BEP) of Sn versus Sn effusion cell temperature for finding coefficients ΔHₑ and P_{O}, in accordance with one embodiment of the present invention.

FIG. 5A illustrates a plot showing logarithmic temperature change versus linear temperature change of Sn effusion cell temperature and their effects on the BEP change against time, in accordance with one embodiment of the present invention.

FIG. 5B illustrates a plot showing logarithmic decrease to ramp rate versus constant (linear) ramp rate versus time to change the same final pressures (9.63*10-9 Torr to 2.35*10-7 Torr)/effusion cell temperature (1093.15 K to 1298.15 K) as a direct comparison against FIG. 5A.

FIG. 6A, FIG. 6B, and FIG. 6C illustrate plots consisting of omega-2theta (004) scans and simulation performed using XRD with simulations of the 4, 10, and 16% samples, in accordance with one embodiment of the present invention.

FIG. 6D, FIG. 6E, and FIG. 6F illustrate plots consisting of the RSM from the (-2-24) crystal planes, in accordance with one embodiment of the present invention.

FIG. 7A, FIG. 7B, FIG. 7C, and FIG. 7D illustrate SIMS Sn concentration versus depth profiles for samples 4%, 10%, 16% at the 1*α grading rate, and sample 14.6% at the 0.5*α grading rate, respectively, in accordance with one embodiment of the present invention.

FIG. 8A, FIG. 8B, and FIG. 8C illustrate plots for samples 4%, 10%, and 16%, representing XRD RSM translated into in-plane and out-of-plane strain versus composition, in accordance with one embodiment of the present invention.

FIG. 9A, FIG. 9B, FIG. 9C, and FIG. 9D illustrate linear gradient GeSn 1*α rate versus 0.5*α rate comparison of RSM (FIG. 9A and FIG. 9B), and strain maps (FIG. 9C, and FIG. 9D), in accordance with one embodiment of the present invention.

FIG. 10A, FIG. 10B, and FIG. 10C illustrate FWHM omega rocking curves of the GeSn gradients in arcseconds, in accordance with one embodiment of the present invention.

FIG. 11A, FIG. 11B, and FIG. 11C illustrate AFM images representing the surface morphology of samples 4%, 10% and 16%, respectively, in accordance with one embodiment of the present invention.

### DETAILED DESCRIPTION OF THE PREFERRED EMBODIMENT

The following detailed description set forth below in connection with the appended drawings is intended as a description of exemplary embodiments in which the presently disclosed invention may be practiced. The term “exemplary” used throughout this description means “serving as an example, instance, or illustration,” and should not necessarily be construed as preferred or advantageous over other embodiments. The detailed description includes specific details for providing a thorough understanding of the presently disclosed method for molecular beam epitaxy (MBE) growth of linearly graded germanium-tin (GeSn) films. However, it will be apparent to those skilled in the art that the presently disclosed invention may be practiced without these specific details. In some instances, well-known structures and devices are shown in functional or conceptual diagram form in order to avoid obscuring the concepts of the presently disclosed method for molecular beam epitaxy (MBE) growth of linearly graded germanium-tin (GeSn) films. It should be noted that this linear grading methodology can be applied to any element/molecule that can be evaporated and or is already in vapor form to create linearly graded alloys/materials. Depending on the control method to cause the evaporation or method to modulate the flow of elements/molecules then it's possible that the meaning of the coefficients, constants and control/output variables within the equations may change however, the general logic can still be applied.

In the present specification, an embodiment showing a singular component should not be considered limiting. Rather, the invention preferably encompasses other embodiments including a plurality of the same component, and vice-versa, unless explicitly stated otherwise herein. Moreover, the applicant does not intend for any term in the specification to be ascribed an uncommon or special meaning unless explicitly set forth as such. Further, the present invention encompasses present and future known equivalents to the known components referred to herein by way of illustration.

It will be understood that, although the terms first, second, third, etc. may be used herein to describe various elements, components, regions, and/or sections, these elements, components, regions, and/or sections should not be limited by these terms. These terms are only used to distinguish one element, component, region, and/or section from another element, component, region, and/or section.

It will be understood that the elements, components, regions, and sections depicted in the figures are not necessarily drawn to scale.

Although the present invention provides a description of a method for molecular beam epitaxy (MBE) growth of linearly graded germanium-tin (GeSn) films, it is to be further understood that numerous changes may arise in the details of the embodiments of the method for molecular beam epitaxy (MBE) growth of linearly graded germanium-tin (GeSn) films and other linear gradients consisting of other types of elements. It is contemplated that all such changes and additional embodiments are within the spirit and true scope of this disclosure.

The following detailed description is merely exemplary in nature and is not intended to limit the described embodiments or the application and uses of the described embodiments. As used herein, the word “exemplary” or “illustrative” means “serving as an example, instance, or illustration.” Any implementation described herein as “exemplary” or “illustrative” is not necessarily to be construed as preferred or advantageous over other implementations. All of the implementations described below are exemplary implementations provided to enable persons skilled in the art to make or use the embodiments of the disclosure and are not intended to limit the scope of the disclosure.

The present invention presents a method for molecular beam epitaxy (MBE) growth of linearly graded germanium-tin (GeSn) films using a logarithmic-based algorithm. The algorithm is configured to dynamically control the Sn effusion cell temperature (T_{Sn}) to achieve a linear increase in Sn beam equivalent pressure (BEP). This ensures precise control over the Sn composition gradient.

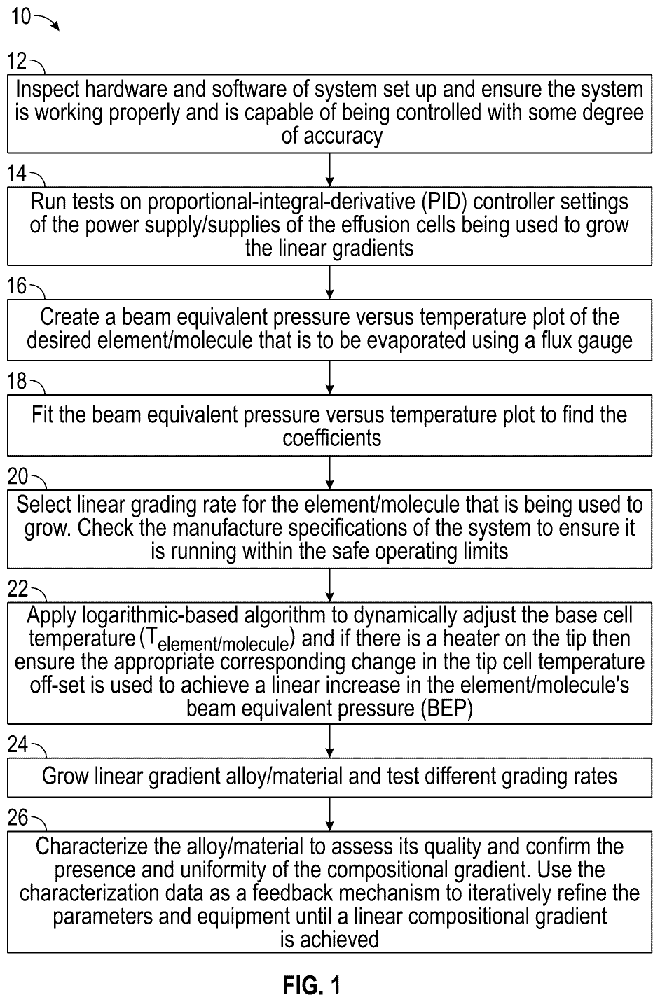

FIG. 1 shows a method 10 for calibrating a Molecular Beam Epitaxy (MBE) system (not shown) to grow linearly graded alloys/materials, in accordance with one exemplary embodiment of the present invention. The order in which method 10 is described should not be construed as a limitation, and any number of the described method blocks can be combined in any order to implement method 10 or alternate methods. Additionally, individual blocks may be deleted from method 10 without departing from the spirit and scope of the subject matter described herein. For simplicity, in the embodiments described below, method 10 may be implemented using the Molecular Beam Epitaxy (MBE) system.

Method 10 starts at step 12. At step 12 an operator checks the MBE system's hardware and software. The MBE system step is checked to ensure all parts work well and the MBE system can control growth with high accuracy. For growing germanium-tin films, checking the MBE is important to ensure the germanium and tin effusion cells work right, the temperature controllers are well-calibrated, and the vacuum is good for high-quality growth. At step 14, the operator tests the Proportional-Integral-Derivative (PID) controller settings for the effusion cell power supplies. The PID controller settings are adjusted to avoid temperature overshoots in the gradient range. The PID controller settings directly affect how linear the gradients will be, and any problems can cause uneven composition profiles. For germanium-tin growth, precise control of the tin effusion cell temperature is critical because temperature and beam pressure have an exponential relationship. Even small temperature changes can greatly affect the tin flux and the film composition, which could disrupt the linear gradient.

At step 16, the operator creates a beam equivalent pressure (BEP) versus temperature plot for the element or molecule to evaporate. A flux gauge measures the BEP at various effusion cell temperatures. For the tin source, this calibration is essential as it shows the basic relationship between tin effusion cell temperature and tin flux. The operator measures the BEP at multiple temperature points across the operating range (e.g., from 1093.15 K to 1298.15 K) to create a full calibration curve. This data helps derive parameters for the logarithmic-based algorithm that enables linear composition grading.

At step 18, the operator fits the beam equivalent pressure versus temperature plot with equation 1 to find the coefficients ΔHₑ and P_{O}. The equation used is:

$${P}_{Sn} = {P}_{0} {e}^{\frac{- Δ {H}_{e}}{{RT}_{Sn}}} \qquad ( Equation 1 )$$

In the above equation, P_{Sn} represents the BEP of the tin (Sn) source, T_{Sn}). is the base temperature of the (Sn) effusion cell in Kelvin, R is the gas constant, (ΔHₑ) is the molar heat of evaporation, and (P_{O}) represents the constant of integration. This fitting process helps to measures the exponential relationship between temperature and BEP that must be adjusted to achieve linear compositional grading.

At step 20, the operator selects a linear grading rate that is being used to grow the film. This selection follows manufacturer specifications of the MBE system to ensure that the MBE system is running within safe operating limits. The operator also considers the type of elements/molecules being evaporated and the type of crucible being used to ensure safe operation and thus avoid breaking the crucible. For germanium-tin growth, this involves setting the rate at which tin composition will increase during film growth. In one example, different grading rates (1*α and 0.5*α) to achieve different composition profiles and to study how the grading rate affects strain management and defect formation in the GeSn films.

At step 22, the operator applies a logarithmic-based algorithm to dynamically adjust the base cell temperature (T_{element/molecule}). If the effusion cell has a tip heater, the operator ensures a proper change in the tip cell temperature offset. This helps to achieve a linear increase in the element/molecule's beam equivalent pressure (BEP) over time. In the present invention, the logarithmic algorithm helps to change the exponential relationship between temperature and BEP into a linear relationship between BEP and time. For the tin effusion cell, the algorithm uses the equation:

$${T}_{Sn} = \frac{- Δ {H}_{e}}{R ln ( \frac{at + b}{{P}_{0}} )} \qquad ( Equation 2 )$$

In the above equation (2), BEP of Sn is designed to follow a linear equation with respect to growth time (t), as expressed by αt+b. The variable (α) represents the rate of BEP change across time, while (b) is the offset variable that sets the starting BEP at t=0. In one example, a dual-filament tin effusion cell with a base temperature and a +50 K tip temperature offset is used to ensure even tin flux and prevent material buildup at the tip (or to stop the material from coalescing at the tip).

At step 24, the operator grows a linear gradient alloy/material and tests different grading rates. This involves growing several samples with varying composition gradients to find the best growth parameters. In the present invention, GeSn films with different final tin compositions (4%, 10%, 16%, 14.6%) and different grading rates (1*α and 0.5*α) are grown. The growth process involves preparing a GaAs substrate, growing a GaAs buffer layer, and then growing the linearly graded GeSn film while keeping a constant germanium BEP and adjusting the tin effusion cell temperature using the logarithmic algorithm. The growth temperature is controlled with a manipulator temperature gradient from 200 to 90° C. at a ramp rate of 10° C./min to optimize tin incorporation and film quality.

At step 26, the operator tests the grown alloy/material to check its quality and confirm the composition gradient is even. The testing is performed using X-ray diffraction (XRD), secondary ion mass spectrometry (SIMS), and atomic force microscopy (AFM). The data from the tests helps to refine parameters and equipment settings until a linear composition gradient is achieved. For the GeSn films, XRD is used to analyze crystal structure, strain state, and composition through reciprocal space mapping (RSM) and omega-2theta scans. SIMS provided depth profiles of tin concentration, confirming the linear grading achieved through the logarithmic algorithm. AFM examined surface smoothness, with the grown films showing surface roughness from 0.337 to 2.8 nm. The test results proves that the logarithmic algorithm effectively produces high-quality, linearly graded GeSn films with controlled strain management and fewer defects.

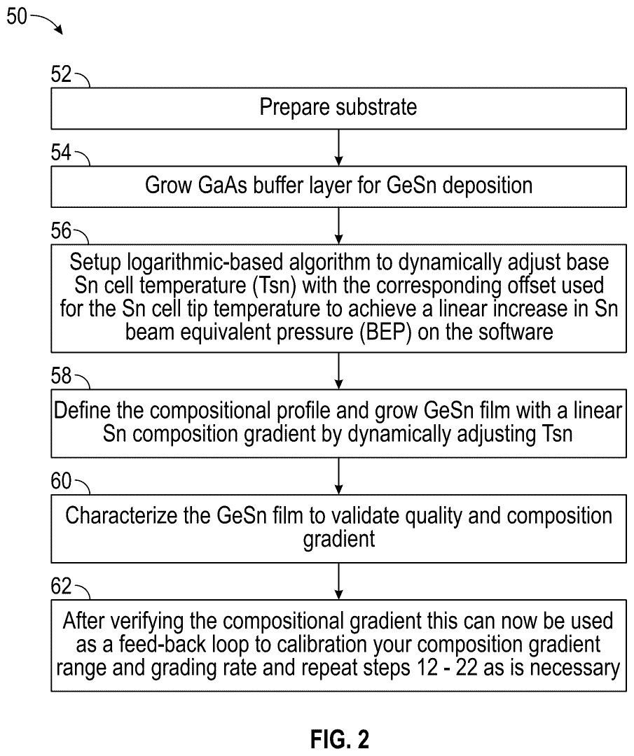

FIG. 2 shows a method 50 for molecular beam epitaxy (MBE) growth of linearly graded germanium-tin (GeSn) films using a logarithmic-based algorithm, in accordance with one exemplary embodiment of the present invention. The order in which method 50 is described should not be construed as a limitation, and any number of the described method blocks can be combined in any order to implement method 50 or alternate methods. Additionally, individual blocks may be deleted from method 50 without departing from the spirit and scope of the subject matter described herein. Furthermore, method 50 can be implemented in any suitable hardware, software, firmware, or combination thereof. However, for ease of explanation, in the embodiments described below, method 50 may be implemented using a Molecular Beam Epitaxy (MBE) system (not shown).

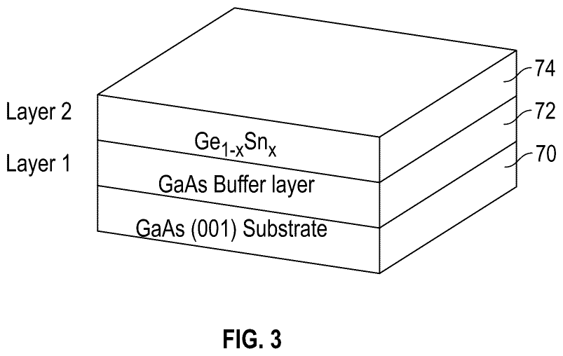

Method 50 begins at step 52, where the operator selects undoped GaAs (001) substrates 70. FIG. 3 shows layers of Gallium Arsenide (GaAs) (001) substrate 70, a GaAs buffer layer 72, and a GeSn film 74, in accordance one exemplary embodiment of the present invention. Substrates 70 are degassed at 300° C. for 2 hours in a preparation chamber to eliminate surface contaminants. In one example, GaAs (001) substrates 70 are transferred through a vacuum transfer line (not shown) to a main MBE chamber (not shown) to prevent exposure to ambient conditions. In main MBE chamber, surface oxides are removed under arsenic flux to expose a clean, crystalline GaAs lattice suitable for high-quality epitaxy. The high-temperature degassing and the arsenic flux treatment creates an oxide free surface.

At step 54, a 230 nm GaAs buffer layer 72 is grown at 585° C. to create a smooth atomically flat surface for GeSn deposition. In order to ensure stoichiometric growth, an arsenic-to-gallium flux ratio of 15:1 is maintained. In one example, the growth temperature of GaAs buffer layer 72 is monitored using a bandit system. The bandit system provides real-time feedback to. In the present invention, GaAs buffer layer 72 is utilized to smoothen the surface after oxide removal. This helps to ensure the GeSn epitaxy starts off with an atomically smooth surface to grow on.

In the present invention, GeSn growth is grown with a constant Ge beam equivalent pressure (BEP) of 2.376×10⁻⁷ Torr with a manipulator temperature gradient ranging from 200 to 90° C. at a ramp rate of 10° C./min. In these examples, Sn cell temperature of a dual-filament effusion cell is set with a base temperature (T_{Sn} and a +50 K tip temperature offset. This offset may help to compensate for thermal gradients within the effusion cell helping to prevent material from collecting at the tip and enhance flux consistency. It should be noted that whatever offset that is used for during the calibration of the Sn BEP versus temperature fitting should also be used during the growth. Failure to do this is likely to result in unexpected changes in BEP at a given temperature which can cause changes in the grading profile.

In order to grow linearly graded GeSn film 74, method 50 provides a linearly increasing flux or equivalent BEP of Sn during the growth. This requires an understanding of how the BEP of Sn (P_{Sn}) changes with respect to a change in Sn cell temperature (T_{Sn}). This can be described as an exponential relationship with reference to a change in temperature, as shown in Equation (1):

$${P}_{Sn} = {P}_{0} {e}^{\frac{- Δ {H}_{e}}{{RT}_{Sn}}} \qquad ( Equation 1 )$$

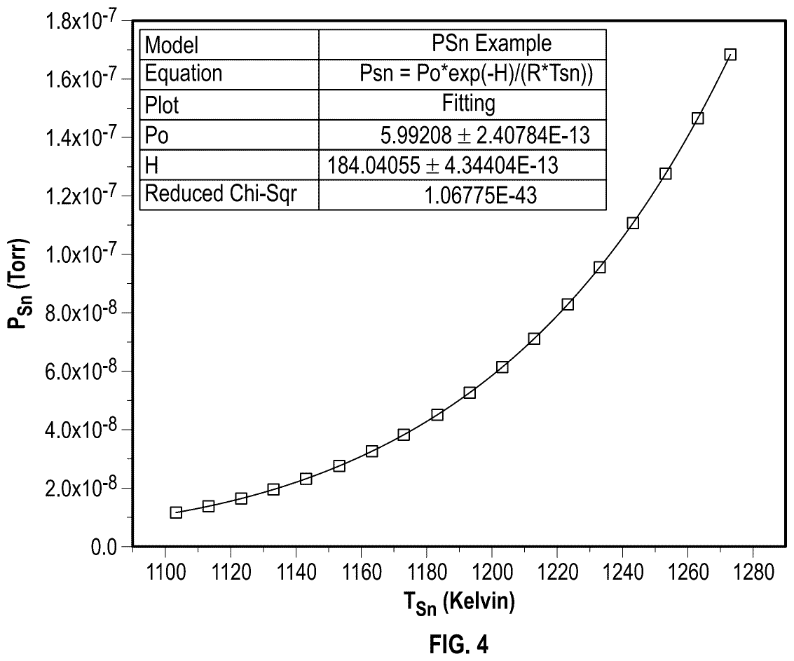

In the above equation, P_{Sn} represents the BEP of the tin (Sn) source, T_{Sn}). is the base temperature of the (Sn) effusion cell in Kelvin, R is the gas constant, (ΔHₑ) is the molar heat of evaporation, and (P_{O}) represents the constant of integration. Both (ΔHₑ) and (P_{O}) depend on material properties, which are ascertained through fitting Equation (1) to a (P_{Sn}) versus (T_{Sn}) plot taken for the Sn cell across a range of temperatures using a flux gauge. An example of BEP of Sn versus Sn cell temperature plot for finding coefficients ΔHₑ and P_{O} is shown in FIG. 4. The graph illustrates the exponential relationship between Sn BEP (P_{Sn}) and Sn cell temperature (T_{Sn}), measured using a flux gauge across a range of temperatures. By fitting Equation (1) to this data, a precise relationship is established for controlling Sn flux. Due to this exponential relationship, a linear ramp of the cell temperature (T_{Sn}) invariably produces an exponential increase in the material flux (rate change) (P_{Sn}), leading to an uncontrolled, exponential compositional gradient in the growing film. This has been a limitation in the prior art for achieving graded semiconductor structures.

The present invention addresses the limitation by defining a linear flux profile as a function of time (t). A logarithmic-based algorithm (logarithmic function) is applied to dynamically adjust base Sn cell temperature (T_{Sn}) to achieve a linear increase in Sn beam equivalent pressure (BEP), as shown at step 56. The logarithmic-based algorithm utilizes the below equation.

$${T}_{Sn} = \frac{- Δ {H}_{e}}{R ln ( \frac{at + b}{{P}_{0}} )} \qquad ( Equation 2 )$$

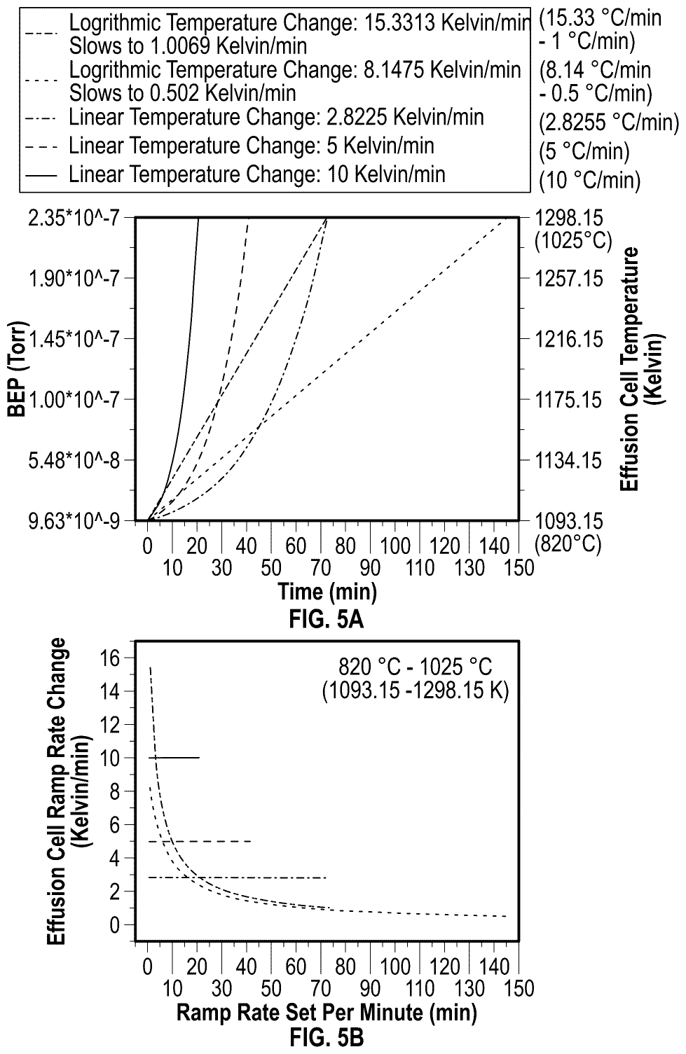

In the above equation (2), BEP of Sn is designed to follow a linear equation with respect to growth time (t), as expressed by αt+b. The variable (α) represents the rate of BEP change across time, while (b) is the offset variable that sets the starting BEP at t=0. Alternatively, (b) can be equated to (P_{Sn}) and solved directly through Equation (1) by setting (T_{Sn}) to the desired starting temperature. FIG. 5A demonstrates the difference of how the BEP change across time is affected by the logarithmic function fitting control of BEP via the logarithmic change in temperature versus a linear change in temperature across time while FIG. 5B demonstrates the corresponding effusion cell ramp rate changes across time to achieve such growths. When applying the above equation, (T_{Sn}) is considered as base Sn cell temperature of the dual-filament effusion cell, while the tip temperature is set separately to follow its change by a 50 K offset with the considerations of your MBEs capabilities in mind as determined by the manufacturers specifications as well as the normal MBE calibration processes as shown in FIG. 1 The values of the variables used in Equation (2) for the growth of these samples are shown in Table 1.

Table 1: Coefficients/variables and T_{Sn} temperature range used in growths.

TABLE 1

| Variables/Coefficients | Values | |
|---|---|---|
| R | $8.314459 \times 1 {0}^{- 3} \frac{kJ}{mol * K}$ | |
| a | $5.1943 \times 1 {0}^{- 10} \frac{Torr}{min}$ | |
| b | 9.62999 × 10⁻⁹ Torr | |
| ΔHₑ | $184.04055 \frac{kJ}{mol}$ | |
| P₀ | 5.99208 Torr | |
| Samples at (1*a) rate | T_{Sn} at start (K) | T_{Sn} at end (K) |
| 4% | 1093.15 | 1207.85 |
| 10% | | 1273.15 |
| 16% | | 1298.15 |
| Sample at (0.5*a) rate | | T_{Sn} at end (K) |
| 14.6% | | 1298.15 |

Within, the three samples' growths of samples 4%, 10%, and 16% the BEP rate change of Sn (a) was selected as

$$a = 5.1943 \times {10}^{- 10} \frac{Torr}{min}$$

to allow for a 15.33 K effusion cell ramp rate change as the starting point of the logarithmic function. FIG. 5A shows a plot for pressure/effusion cell temperature versus time illustrating a linear gradient change in temperature logarithmically. The linear gradient method helps to predict growth, and increase control over the growth. Further, it helps to control the state of strain. FIG. 5B shows a plot for pressure/effusion cell ramp rate set point versus time. The logarithmic rate changes represent the linear gradients and linear rate change represents the exponential gradients. In addition to the three samples grown at the (1*α) rate and another sample by the name of 14.6% grown with a rate of (0.5*α) to compare against sample 16%. Here, Ge effusion cell temperature is also fixed at 1260° C. While the Sn effusion cell temperature range of sample 14.6% was sample 16%. The manipulator temperature is set to change from 200-90° C. at a ramp rate of 10° C./min. At the end of each growth an additional 7 minutes were added at the final gradient temperature.

At step 58, the GeSn films are grown with a linear Sn composition gradient by dynamically adjusting T_{Sn} according to Equation (2). Here, at the (1*α) grading rate the start all of the gradients started from a composition near Ge_{0.998}Sn_{0.002} at T_{Sn}=1093.15 K. The three samples were grown to Ge_{0.96}Sn_{0.04} at T_{Sn}=1207.85 K, Ge_{0.9}Sn_{0.1} at T_{Sn}=1273.15 K and Ge_{0.84}Sn_{0.16} at T_{Sn}=1298.15 K as shown in Table 1. Sample 4% was grown to was terminated to was growth to at T_{Sn}=1207.85 Additionally, composition data points may be used to replace P_{Sn} in the pressure versus temperature plot and fitted again to predict composition versus T_{Sn}. SIMS or a comparable method to get a composition versus depth profile should be used to increase the accuracy of composition targeting and determine the grading rate. It is preferable to couple it with XRD in order to distinguish crystal structure with reference to composition. The grading rate can be used to control strain changes through linear grading, thus reduces defect formation and enhances film quality.

At step 60, the GeSn film is characterized using advanced techniques to validate its quality (structural and strain) and composition. In some examples, atomic force microscopy (AFM), X-ray diffraction (XRD), and secondary ion mass spectrometry (SIMS) are used as the primary characterization tools. The AFM used for tapping mode measurements to observe the surface roughness and morphology. The XRD was used to observe the strain profile and GeSn compositions via reciprocal space mapping (RSM) and omega-2theta scans of the grown films. The SIMS is performed to obtain a depth profile of the GeSn film composition, say near 4%, 10%, and 16%. The data from SIMS may be used to increase the accuracy of composition targeting. It is preferable to use XRD and RSM to analyze the crystal structure with reference to the GeSn film composition.

In order to validate the presently disclosed method, four samples are grown using the logarithmic-based function to linearize the change in Sn flux, resulting in samples with final crystalline compositions near 4%, 10%, and 16% at the 1*α rate and 14.6% at the 0.5*α grading rate. The Sn composition of each sample is determined from the RSM data by defining the evidenced lattice mismatch as a function of the local Sn content at each lattice location. To do so, the relaxed parameter

$${a}_{0}^{GeSn}$$

of the GeSn alloy and its set of elastic constants,

$${C}_{11}^{GeSn} and {C}_{12}^{GeSn} ,$$

can be described in terms of Vegard's law as follows.

$${a}_{0}^{GeSn} = {xa}_{0}^{Sn} + ( 1 - x ) {a}_{0}^{Ge} \qquad ( Equation 3 a )$$

$${C}_{11 , 12}^{GeSn} = {xC}_{11 , 12}^{Sn} + ( 1 - x ) {C}_{11 , 12}^{Ge} \qquad ( Equation 3 b )$$

By solving equations 3a and 3b for x, method 50 presents a new equation to calculate Sn content from the components of the scattering vectors Qₓ and Q_{z} by:

$$x = α - \sqrt{{α}^{2} - β} \qquad ( Equation 4 )$$

Here, parameters α and β are functions of the in-plane and out-of-plane lattice parameters

$${a}_{\vert \vert}^{GeSn} and {a}_{⊥}^{GeSn} , ,$$

as shown in Table 2, which are given by

$${a}_{\vert \vert}^{GeSn} = 2 π \sqrt{( {h}^{2} + {k}^{2} ) / {Q}_{x}^{2}} and {a}_{⊥}^{GeSn} = 2 π l / {Q}_{z}$$

for an asymmetrical hkl reflection.

Table 2: Relaxed lattice parameters and elastic constants of Sn and Ge, as well as the functions α and β used in Eq. (4)

TABLE 2

| | |
|---|---|
| a₀^{Sn}(nm) | 0.6489 |
| a₀^{Ge}(nm) | 0.5658 |
| C₁₁^{Sn}(GPa) | 69 |
| C₁₂^{Sn}(GPa) | 29.3 |
| C₁₁^{Ge}(GPa) | 126 |
| C₁₂^{Ge}(GPa) | 44 |
| α | $2.0474 {a}_{\vert \vert}^{GeSn} + 3.96945 {a}_{⊥}^{GeSn} - 2.16591$ |
| β | $12.25654 {a}_{\vert \vert}^{GeSn} + 17.54914 {a}_{⊥}^{GeSn} - 16.86405$ |

At step 62, after verifying the compositional gradient, the results are used as a feed-back loop to calibrate the composition gradient range and grading rate. If required, the step 52 through step 62 are repeated.

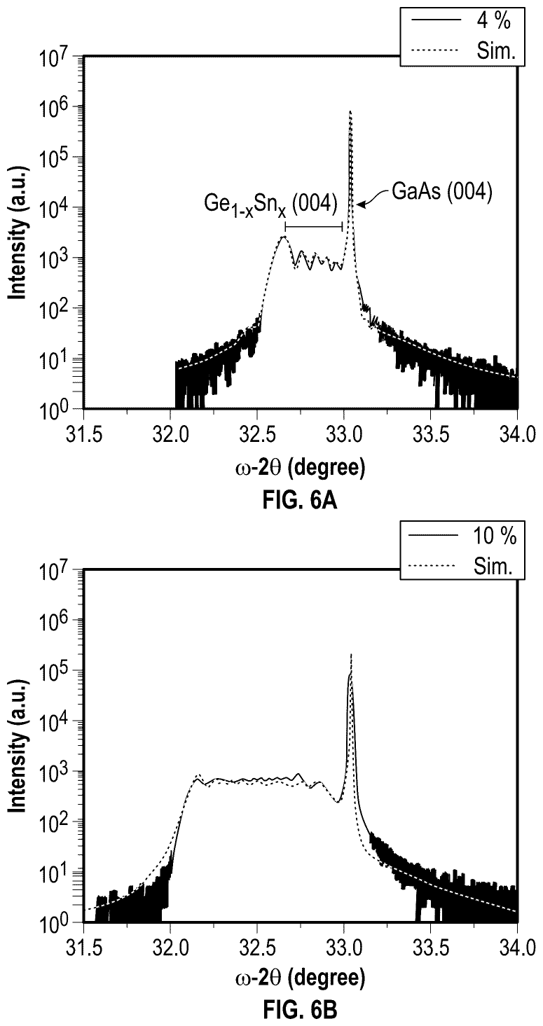

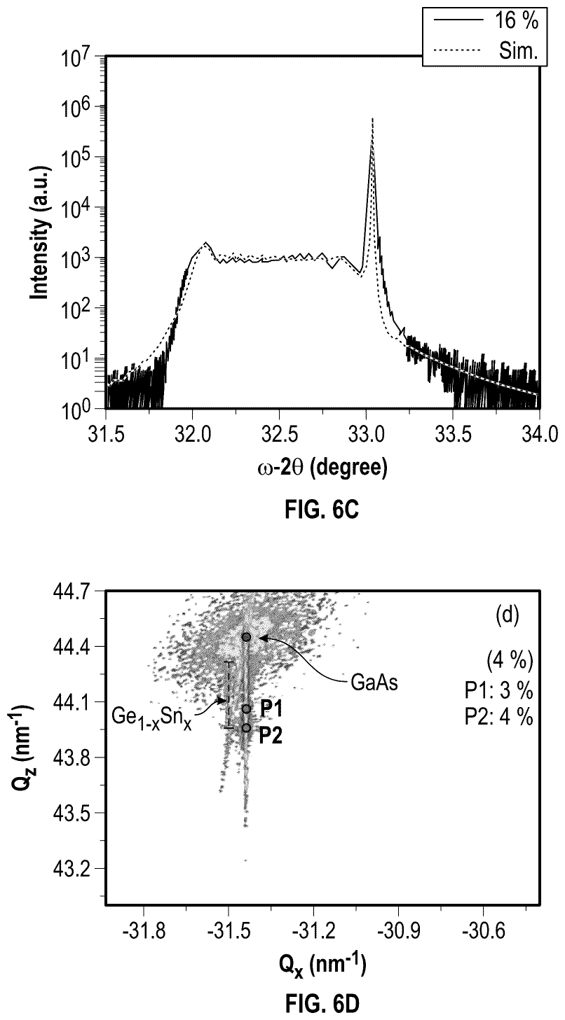

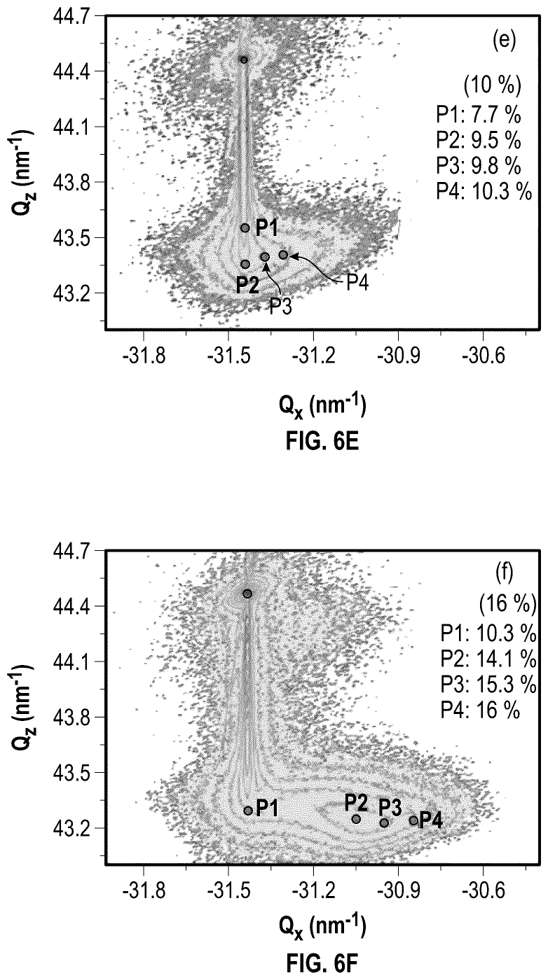

FIG. 6A, FIG. 6B, and FIG. 6C show plots consisting of both omega-2theta (004) scans and simulation performed using XRD with simulations of the 4, 10, and 16% samples. FIG. 6D, FIG. 6E, and FIG. 6F show plots consisting of the RSM from the crystal planes. The XRD RSM intensity change is observed as a gradient in color from the highest intensity to the lowest intensity. The RSM Sn percentage positions are calculated using the Equation (4) presented above.

The RSM shown in FIG. 6D, FIG. 6E, and FIG. 6F indicates that the in-plane lattice parameters α_{∥}^{GeSn} remain nearly unchanged for compositions of Sn up to 8-10%, indicating a pseudomorphic growth of GeSn. The pseudomorphic region is the result of managing the Sn distribution across the thickness and its resultant effect on the strain, leading to stabilization of the parallel lattice parameters α_{∥}^{GeSn}. This phenomenon may be attributed to the interplay between composition and its associated critical thickness, suggesting a correlation that enables the system to sustain such strain characteristics even amid substantial changes in composition. The addition of 7 min of GeSn growth at the end shows that the 4% sample continues to grow fully strained. The next sample, which continues the function to 10%, begins to show the start of a relaxation process, as seen in the RSM depicted in FIG. 6E. The same pseudomorphic growth is observed for much of the film until the composition approaches 10%, which is evidenced by the expansion of the

$${a}_{\vert \vert}^{GeSn}$$

lattice parameters. At this point, the 7 min growth at the end becomes more apparent, and it is observed that the structure begins to relax, which can be attributed to the curvature in the tail of the RSM. The last sample grown with a crystal composition near 16% shows that the structure stops its expansion of the out-of-plane lattice parameter

$${a}_{⊥}^{GeSn} , ,$$

while its in-plane lattice parameters α_{∥}^{GeSn} begin to expand in order to continue adding Sn to its structure. This is evidenced in FIG. 6F, where the elongation line is expanding consistently parallel to the Qₓ axis, while Q_{z} maintains its position. This suggests that two types of GeSn regions appear for the 16% sample, fully strained (pseudomorphic) and a graded relaxation region up to 60%.

Simulations consisting of (004) omega-2theta scans were carried out to define the Sn depth distribution and to confirm the maximum Sn concentration. FIG. 6A, FIG. 6B, and FIG. 6C plots consist of both omega-2theta (004) scans and simulation performed using XRD with simulations of the 4, 10, and 16% samples. The simulations were performed taking into account the strain state of the layers according to XRD-measured RSM. The best fit for each sample was obtained for a linear Sn depth profiling distribution in the GeSn layers. The initial and final Sn concentrations are presented in Table 3.

Table 3: Simulation results of GeSn films.

TABLE 3

| | | Initial Sn | Final Sn |
|---|---|---|---|
| Sample | Layer | concentration (%) | concentration (%) |
| 4% | Pseudomorphic | 0 ± 0.5 | 3.9 ± 0.5 |
| 10% | Pseudomorphic | 0.5 ± 0.5 | 9.8 ± 0.5 |
| 16% | Pseudomorphic | 0.5 ± 0.5 | 10 ± 0.5 |
| | Partly relaxed up | — | 15.5 ± 0.5 |
| | R ≈ 60% | | |

As can be seen, thickness fringes are observed in the measured XRD omega-2theta scan for the 4% sample, which is used in Equation (5), presented below.

$${t}_{{Ge}_{1 - x} {Sn}_{x}} = \frac{( {n}_{1} - {n}_{2} ) λ}{2 ( sin {θ}_{1} - sin {θ}_{2} )} \qquad ( Equation 5 )$$

Here, λ is the X-ray wavelength, θ is the peak position, and n is the peak order. This allows the calculation of the estimated Ge₁₋ₓSnₓ total layer thickness, resulting in

$${t}_{{Ge}_{1 - x} {Sn}_{x}} = 112 \pm 5 nm .$$

The simulated results of the growth agrees well with this thickness calculation and allows the separation of the approximate thicknesses for the 18 min Ge₁₋ₓSnₓ gradient and the additional 7 min worth of growth at composition, resulting in a thickness of 75±5 and 35±5 nm, respectively, for a sum thickness near 110 nm. The simulation also agrees with the maximum composition values calculated from Equation (4) for the three samples. In the case of the 16% sample, the simulation was performed according to RSM by creating a model consisting of a fully strained layer followed by a partly relaxed GeSn layer. The best fit was obtained for a maximum of 10±0.5% Sn concentration in the pseudomorphic region and about 15.5±0.5% for the partly relaxed region.

Another feature that can be observed from the RSM of the three samples is that each subsequent sample with a higher Sn composition also results in a larger Qₓ width for the pseudomorphic region. This is due to defect propagation or related to the act of growing additional material at the higher compositions along the gradient (larger lattice constants), causing additional strain to be applied to the underlining lattice structure, resulting in the in-plane lattice constants of the lower compositions expanding. A similar trend in which the FWHM of rocking curves increases within the pseudomorphic region with respect to the three samples can be observed.

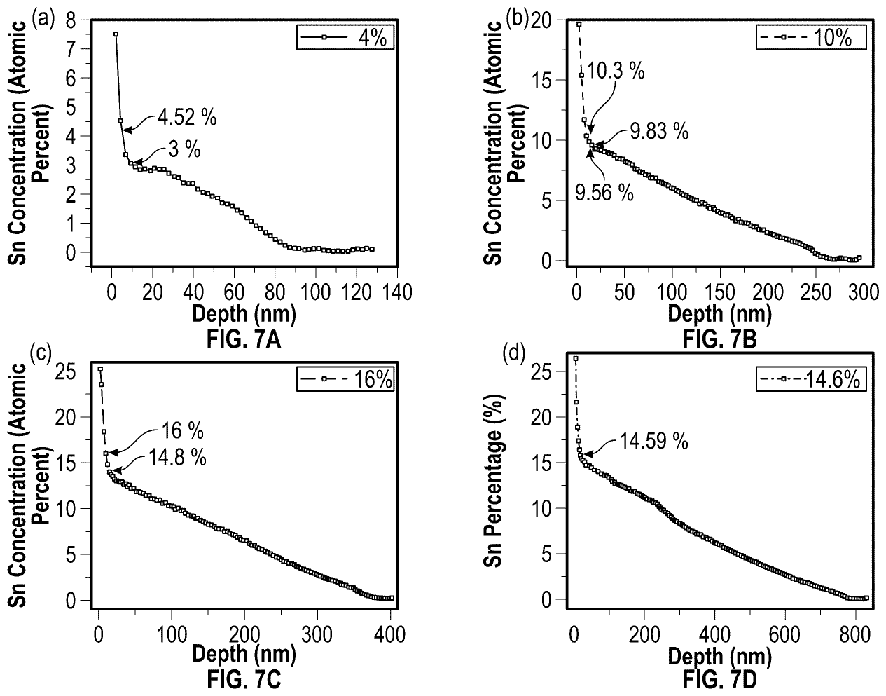

In addition, SIMS characterization can be conducted to confirm the alloying of these gradients, as shown in FIG. 7A, FIG. 7B, FIG. 7C, and FIG. 7D. From the SIMS etching profile, it is clear that the Ge₁₋ₓSnₓ composition is changing linearly for the majority of the growth using our logarithmic algorithm to control the Sn cell temperature. Starting with the 4% sample, it can be observed that the linear gradient grows to 3%, as seen in FIG. 7A, and that within the last 7 min of growth, an increase in the Ge₁₋ₓSnₓ crystal structure composition near the 4% mark is observed from the XRD results, as presented in FIG. 6A and FIG. 6D. The linear grading profile is also observed in samples 10%, 16%, and 14.6% in FIG. 7B, FIG. 7C, and FIG. 7D, respectively. In each of the samples, an increase in Sn content exceeding that of the GeSn composition calculations from XRD occurs. Referring to FIG. 7C and FIG. 7D, the linear gradient GeSn rate change comparison (SIMS depth profiles) can also be seen at 1× rate change and 0.5× rate change, respectively.

In order to calculate in-plane and out-plane strain values, Equation (4), Equation (6a) and Equation (6b) are used for three samples.

$${ε}_{\vert \vert}^{GeSn} = \frac{{a}_{\vert \vert}^{GeSn} - {a}_{0}^{GeSn}}{{a}_{0}^{GeSn}} \qquad ( Equation 6 a )$$

$${ε}_{⊥}^{GeSn} = \frac{{a}_{⊥}^{GeSn} - {a}_{0}^{GeSn}}{{a}_{0}^{GeSn}} \qquad ( Equation 6 b )$$

In the above equations,

$${ε}_{\vert \vert}^{GeSn}$$

defines the in-plane strain value, and

$${ε}_{⊥}^{GeSn}$$

defines the out-plane strain value. Further,

$${a}_{\vert \vert}^{GeSn} and {a}_{⊥}^{GeSn}$$

relaxed lattice constant

$${a}_{0}^{GeSn}$$

of its corresponding GeSn composition. Equations (4), Equation (6a) and Equation (6b) are used to plot a three-dimensional of

$${ε}_{\vert \vert}^{GeSn} and {ε}_{⊥}^{GeSn}$$

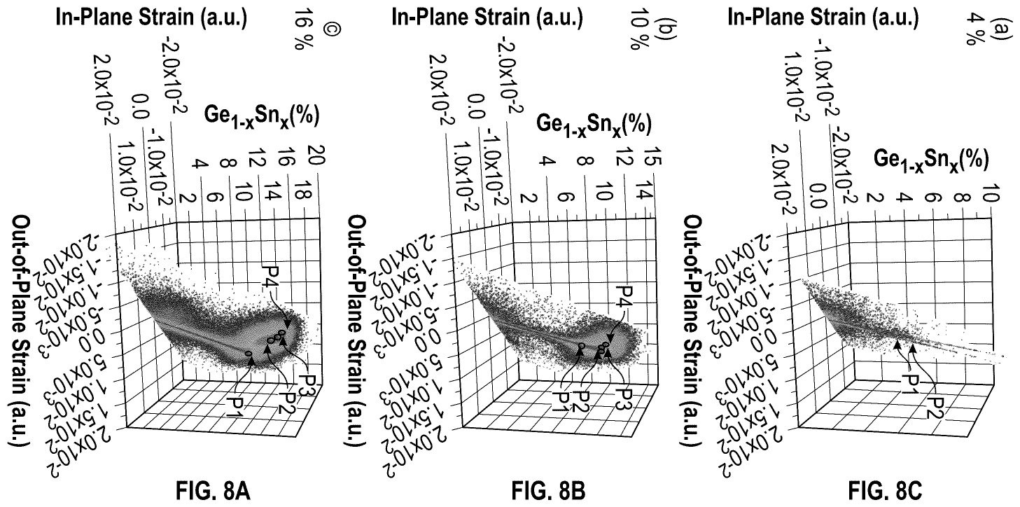

strain versus composition to observe the change in strain versus composition. FIG. 8A, FIG. 8B, and FIG. 8C show the strain versus composition plots for 4%, 10%, and 16% samples. In FIG. 8A, FIG. 8B, and FIG. 8C, points P1, P2, P3, and P4 are inset to match the corresponding RSM composition points in FIG. 6D, FIG. 6E, and FIG. 6F, respectively. Further, the corresponding strain and compositional data are presented in Table 4.

Table 4: Composition and its corresponding in-plane and out-of-plane strains.

TABLE 4

| | | Composition | In-plane | Out-of-plane |
|---|---|---|---|---|
| | | (%) from | strain (a. u.) | strain (a. u.) |
| Sample | Position | Eq. 4 | from Eq. 6a | from Eq. 6b |
| 4% | P1 | 3 | −0.0052 | 0.0037 |
| | P2 | 4 | −0.0066 | 0.0046 |
| 10% | P1 | 7.7 | −0.0122 | 0.0086 |
| | P2 | 9.5 | −0.0148 | 0.0104 |
| | P3 | 9.8 | −0.013 | 0.0092 |
| | P4 | 10.3 | −0.0114 | 0.0081 |
| 16% | P1 | 10.3 | −0.01552 | 0.011 |
| | P2 | 14.1 | −0.009 | 0.0064 |
| | P3 | 15.3 | −0.0074 | 0.0053 |
| | P4 | 16 | −0.0051 | 0.0036 |

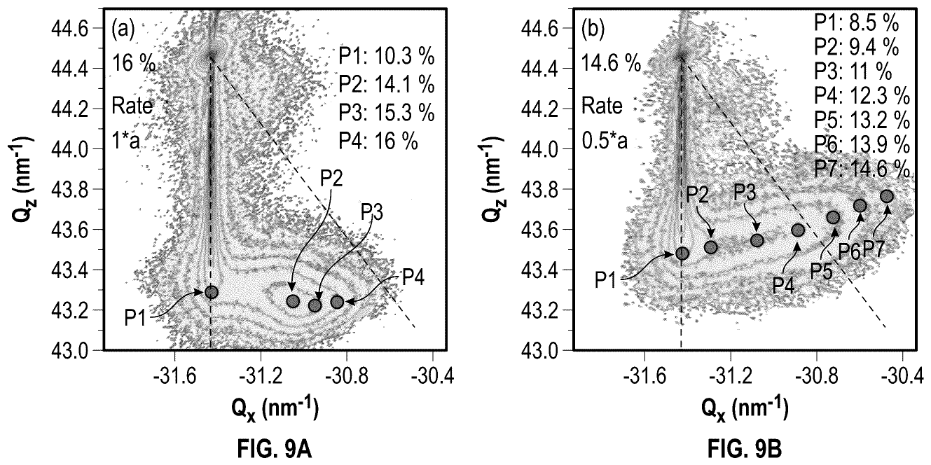

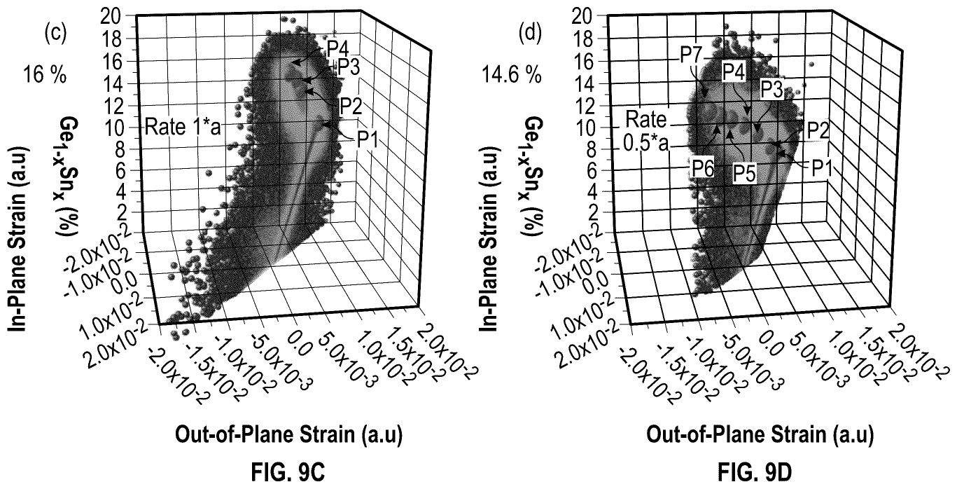

Further, FIG. 9A, FIG. 9B, FIG. 9C, and FIG. 9D show linear gradient GeSn rate comparison of RSM (FIG. 9A and FIG. 9B), and strain maps (FIG. 9C, and FIG. 9D). The strain and corresponding compositional data are presented in Table 5.

Table 5: Composition and its corresponding in-plane and out-of-plane strains.

TABLE 5

| | | | In-plane | Out-of-plane |
|---|---|---|---|---|
| Sample | Position | Sn % | strain % | strain % |
| 16% | P1 | 10.3 | −0.01552 | 1.1 |
| (1x) | P2 | 14.1 | −0.009 | 0.64 |
| | P3 | 15.3 | −0.0074 | 0.53 |
| | P4 | 16 | −0.0051 | 0.36 |
| 14.6% | P1 | 8.5 | −1.28 | 0.9 |
| (0.5x) | P2 | 11 | −0.54 | 0.38 |
| | P3 | 13.2 | 0.28 | −0.198 |
| | P4 | 14.6 | 0.9 | −0.64 |

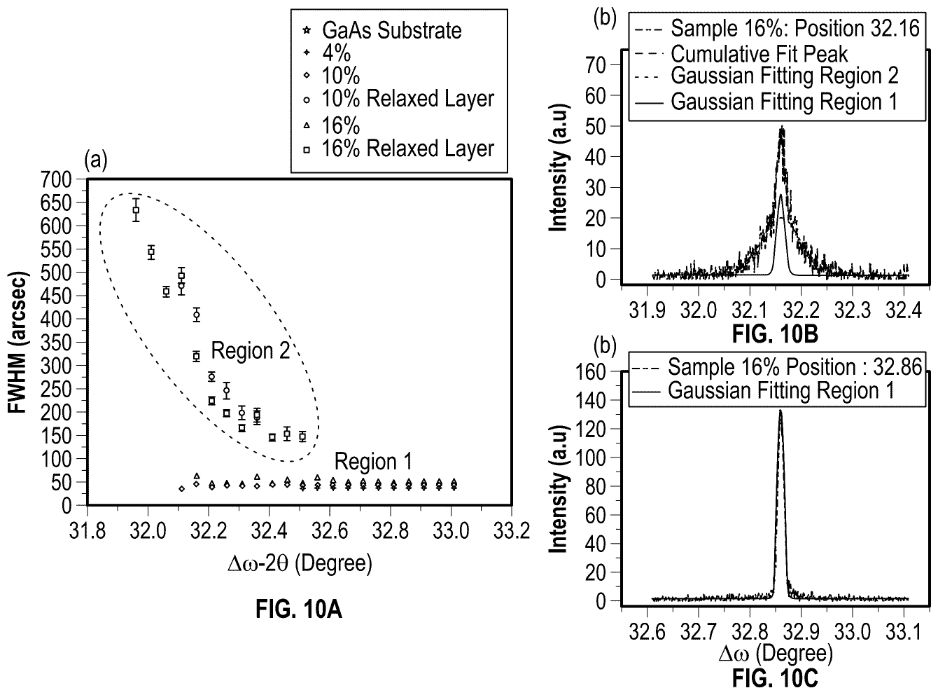

In addition, the film quality is evaluated using omega scans were collected in increments of 0.5 degrees across the whole omega-2theta range of the gradient, as depicted in FIG. 10A, FIG. 10B, and FIG. 10C. FIG. 10A shows a plot of all of the FWHM values from gaussian fittings of both relaxing region 2 and pseudomorphic region. FIG. 10B, and FIG. 10C show plots on how gaussian fittings were used to fit each region. The crystal quality of the epitaxial layers is estimated by obtaining the full width at half maximum (FWHM) for omega rocking curve scans. Near the omega-2theta 32.5-degree mark, it can be seen that the rocking curves begin to form two peaks. An example of this is shown and fitted in FIG. 10B, in which the narrow peak is related to the pseudomorphic region while the broader peak originates from the partially relaxed region. Results from the fittings suggest that for all samples, the pseudomorphic region maintains extremely high-quality levels, ranging from 30-50 arcseconds in the entire omega-2theta range. This compares to about 16 arcseconds for the GaAs substrate. At the same time, the trend of increasing FWHM follows the relaxation process toward the decreasing omega-2theta angle (increasing Sn content). For the 16% sample, it can be seen that an increase in the FWHM in the relaxation region occurs compared to the pseudomorphic region. This decrease in quality is likely due to the relaxation process and defect propagation in the film. These results directly support the claim that gradient-based structures can help mitigate or suppress defect propagation.

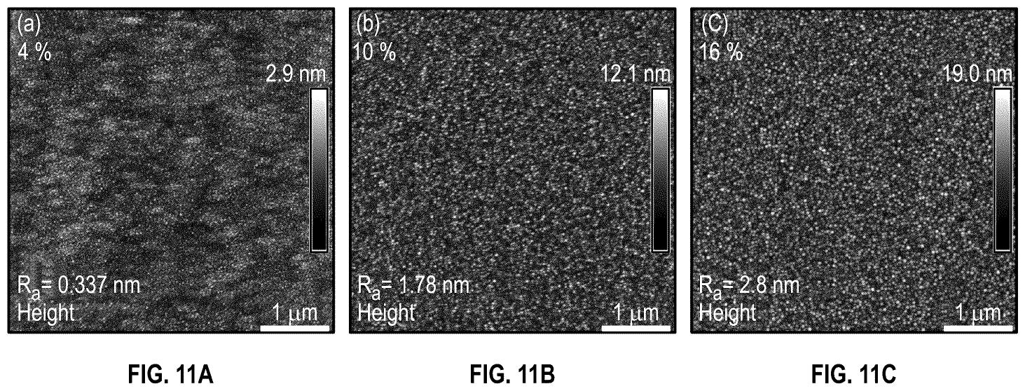

The surface characteristics of the GeSn films depict similar surface features, with one notable exception. In the 16% sample, some observable Sn segregation sites begin to sparsely appear across the surface of the sample, with normal regions in between, as shown in FIG. 11A, FIG. 11B, and FIG. 11C. Within the normal regions small dots are present on the surface which indicates the presence of excess Sn. The 4%, 10%, and 16% samples have an average surface roughness of 0.337, 1.78, and 2.8 nm, respectively.

In some implementations, the surface quality can be further improved by setting a system capable of continuously monitoring the surface temperature of the film with respect to the manipulator thermal couple temperature during growth while having the ability to not only heat the manipulator but also to directly cool it. By coupling this type of system with a eutectic composition tracking algorithm designed to maintain an optimum relationship between the surface temperature of the GeSn film and the specific Sn composition that is being grown at a specific point in time while also relating the algorithm to the sticking coefficient to aid in controlling the incorporation rate of Sn into GeSn, the crystal quality may be significantly improved while achieving higher composition films. Alternatively, it may be possible to use a dummy effusion cell to radiatively heat the surface of the sample to create a temperature gradient between the top of the film and the substrate to aid in crystallizing the GeSn film even further.

The above-described method provides a logarithmic-based algorithm for controlled MBE growth of high-quality, linearly graded Ge₁₋ₓSnₓ films. The GeSn films with crystal qualities near the substrate is achieved. The logarithmic-based algorithm can be used in the applications for the growth of GeSn on different substrate systems, such as germanium, silicon, sapphire, indium arsenide, InGaAs, and silicon carbide. Additionally, the logarithmic-based algorithm can be used to determine the approximate BEP ratio of Sn to Ge in order to obtain specific compositions through a calibration process.

The present methodology applies to material systems such as GeSn or SiGeSn, and extends to any element or molecule that operators can deliver to a substrate via thermal evaporation, electron-beam (E-beam) evaporation, gaseous form or other vapor-phase delivery methods. The underlying methods for creating linear gradients using thermal evaporation via heating filaments can also be used to generate E-beam evaporated linear gradients and precursors introduced in gaseous form such as in CVD systems.

In electron-beam evaporation, operators achieve control over the evaporation flux by modulating the electron beam current, which determines the amount of heating power delivered to the source material. Increasing the current increases the evaporation rate, which enables time-dependent flux control needed for compositionally graded film growth. The beam voltage typically operates as a fixed voltage in the kV range that sets the beam energy. While it influences heating efficiency, operators typically do not vary it during deposition. Operators reserve voltage adjustments for coarse tuning of the evaporation behavior before starting the flux modulation process. Furthermore, operators can control programmable ramp functions to fine-tune evaporation rate by creating control functions that dynamically adjust the current or, if necessary, apply voltage to modulate the electron beam to adjust flux over time in a controlled manner.

Operators can obtain the BEP of the electron beam evaporated material by rotating a flux gauge into the path of the flux. For example, operators can use this to obtain a BEP versus set voltage and varied current plot and then fit it in a similar way as shown with thermal evaporating via heating filaments to obtain the required change in current over time to obtain a linear change in BEP across time. Operators can also use a Quartz Crystal Microbalance (QCM) to measure the mass deposition rate in real time with varied changes in current to the e-beam to evaluate the change in deposition rate from the element/material being evaporated. Operators can also use this to backwards calculate the required change in current across time to create a linearly changing deposition rate using equation 1 and 2 to fit and calculate the required change in current at a given point in time.

Alternatively, operators can directly grow an unknown gradient material/alloy by changing the evaporation rate whether from thermal evaporation via heating filaments or electron beam evaporation via MBE or from precursors introduced in gaseous form such as used in CVD. Each method has their own corresponding control schemes that operators document with respect to the final grown material. Operators can then take this grown material and analyze it, for example by SIMS, Rutherford Backscattering Spectrometry (RBS), X-ray Photoelectron Spectroscopy (XPS) composition versus etching profiles and XRD, to have the composition gradient range versus their corresponding control schemes to then fit with equations 1 and 2 to calculate the required changes in the control scheme to obtain linear gradients.

In CVD type systems, elements or compounds introduced in gaseous form such as through a bubbler or direct gas injection. can be precisely controlled using mass flow controllers (MFCs), which regulate internal valves based on programmable setpoints rather than manual valve position. Operators can dynamically modulate the flow using mass flow controllers (MFCs), which regulate internal valves based on programmable setpoints. Similarly, in systems utilizing manual or motor-actuated valves, operators can achieve flow control by precisely adjusting valve positions over time. This general methodology for obtaining linear gradients can be particularly useful for CVD type systems due to the fact that reaction rate versus actual deposition onto a substrates' surface is not guaranteed to be deposited linearly by changing the flow rate of the precursor gas linearly. While the specific parameters, units, and control mechanisms may differ between solid-source and gas-source systems, the underlying principle of time-dependent modulation to achieve linear composition gradients remains consistent. This approach outlined to create linear gradients enables the growth of a wide range of materials/alloys, including but not limited to GeSn, on various substrates such as germanium, silicon, sapphire, indium arsenide (InAs), indium gallium arsenide (InGaAs), and silicon carbide (SiC) to name a few.

The present invention also encompasses a deposition system (molecular beam epitaxy (MBE) system) for growing linearly graded films with controlled composition gradients. The deposition system may include a deposition chamber (molecular beam epitaxy chamber) configured to maintain controlled conditions suitable for film growth. At least one element or molecule source may be configured to provide a constant beam equivalent pressure (BEP) or flow rate, while a second or more element or molecule source/sources may comprise various configurations depending on the deposition method employed.

In some embodiments, the second or more element or molecule source/sources may comprise of a single filament effusion cell with one temperature zone control or alternatively a dual-filament effusion cell with a base temperature zone control and a tip temperature zone control offset for thermal evaporation applications. Alternatively, the second source may comprise an electron-beam evaporation source with dynamically controlled beam current for precise flux control. In other embodiments, particularly for CVD type systems, the sources may comprise a gaseous precursor delivery system equipped with mass flow controllers (MFCs) or adjustable valves for flow modulation. Bubblers may also be used in this these types of embodiments in which the temperature of the bubble may be modulated in addition or separately from the carrier gas pass through a time constant or time varied modulation.

The deposition system may further include a controller programmed with a time-dependent modulation algorithm. The controller may dynamically adjust the element or molecule source/sources used to achieve a linear increase in beam equivalent pressure (BEP) or flow rate over time, thereby enabling the growth of linearly graded films having linear composition gradients. The controller may execute the time-dependent modulation algorithm based on mathematical relationships that account for the nature of evaporation processes or flow dynamics, transforming these into linear compositional changes through control functions.

This versatile system architecture allows for the controlled growth of various material systems beyond germanium-tin alloys, extending the methodology to any element or molecule that can be delivered through thermal evaporation, electron-beam evaporation, or vapor-phase delivery methods. The underlying principle of time-dependent modulation to achieve linear composition gradients remains consistent across different deposition techniques and source configurations.

In addition to the other benefits this method provides is the ability to create composition profile approximations of advanced compositional grading compositions versus thicknesses. For example, for an arbitrary target profile, including but not limited to polynomial, exponential, sinusoidal, or non-monotonic functions can be implemented as a piecewise-linear approximation over a number “N” segments. By breaking the desired modeled gradient down into time length defined N segments with different BEP/flow rates the more advanced curvature of these functions can be created. Increasing N segments would reduce the approximation error to a specified tolerance. Optional smoothing or overlap windows at segment boundaries can be used to maintain substantial continuity while preserving segment slopes. The smoothing/overlap window is a small time interval centered on the breakpoint where the two segments can be blended so that the composition change is gradual, no abrupt. Outside of the small defined time window, each segment keeps its original slope exactly; only the short transition is smoothed. This could be useful to help reduce or prevent setpoint jerk, tool overshoot which may aid in helping increase the likelihood of obtaining the correct composition.

The present invention has been described in particular detail with respect to various possible embodiments, and those of skill in the art will appreciate that the invention may be practiced in other embodiments. First, the particular naming of the components, capitalization of terms, the attributes, data structures, or any other programming or structural aspect is not mandatory or significant, and the mechanisms that implement the invention or its features may have different names, formats, or protocols. Further, the system may be implemented via a combination of hardware and software, as described, or entirely in hardware elements. Also, the particular division of functionality between the various system components described herein is merely exemplary, and not mandatory; functions performed by a single system component may instead be performed by multiple components, and functions performed by multiple components may instead be performed by a single component.

Some portions of the above description present the features of the present invention in terms of algorithms and symbolic representations of operations on information. These algorithmic descriptions and representations are the means used by those skilled in the data processing arts to most effectively convey the substance of their work to others skilled in the art. These operations, while described functionally or logically, should be understood as being implemented by computer programs.

Further, certain aspects of the present invention include process steps and instructions described herein in the form of an algorithm. It should be noted that the process steps and instructions of the present invention could be embodied in software, firmware, or hardware, and when embodied in software, could be downloaded to reside on and be operated from different platforms used by real-time network operating systems.

The algorithms and operations presented herein are not inherently related to any particular computer or other apparatus. Various general-purpose systems may also be used with programs in accordance with the teachings herein, or it may prove convenient to construct more specialized apparatus to perform the required method steps. The required structure for a variety of these systems will be apparent to those of skill in the, along with equivalent variations. Also, the present invention is not described with reference to any particular programming language. It is appreciated that a variety of programming languages may be used to implement the teachings of the present invention as described herein, and any references to specific languages are provided for disclosure of enablement and best mode of the present invention.

It should be understood that components shown in FIGUREs are provided for illustrative purposes only and should not be construed in a limited sense. A person skilled in the art will appreciate alternate components that may be used to implement the embodiments of the present invention and such implementations will be within the scope of the present invention.

While preferred embodiments have been described above and illustrated in the accompanying drawings, it will be evident to those skilled in the art that modifications may be made without departing from this invention. Such modifications are considered as possible variants included in the scope of the invention.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for growing a linearly graded germanium-tin (Ge₁₋ₓSnₓ) film, said method comprising the steps of:
providing a substrate in a molecular beam epitaxy (MBE) chamber;
establishing a constant germanium beam equivalent pressure (BEP);
applying a logarithmic-based algorithm to dynamically control a tin (Sn) effusion cell temperature to achieve a linear increase in tin (Sn) beam equivalent pressure (BEP) over time; and
dynamically adjusting said tin (Sn) effusion cell temperature for growing a linear graded germanium-tin (Ge₁₋ₓSnₓ) film having a linear tin (Sn) composition gradient based on said logarithmic-based algorithm.

2. The method of claim 1, wherein said logarithmic-based algorithm utilizes an equation:
$${T}_{Sn} = \frac{- Δ {H}_{e}}{R ln ( \frac{at + b}{{P}_{0}} )}$$
where T_{Sn} represents said tin (Sn) effusion cell temperature, R represents a gas constant, ΔHₑ represents a molar heat of evaporation, and P_{O} represents a constant of integration, t represents growth time, α represents a rate of BEP change across time, and b represents an offset variable that sets the starting BEP.

3. The method of claim 1, wherein said substrate comprises Gallium Arsenide (GaAs).

4. The method of claim 1, further comprising growing a buffer layer on said substrate prior to growing said linearly graded film.

5. The method of claim 1, wherein said Sn effusion cell comprises a dual-filament effusion cell with a base temperature and a tip temperature offset to stop the material from coalescing at the tip, or an electron-beam evaporation source with dynamically controlled beam current.

6. The method of claim 1, further comprising characterizing said germanium-tin (Ge₁₋ₓSnₓ) film using atomic force microscopy (AFM), X-ray diffraction (XRD), and secondary ion mass spectrometry (SIMS), Rutherford Backscattering Spectrometry (RBS), X-ray Photoelectron Spectroscopy (XPS) composition versus etching profiles for validating structural, and strain parameters and composition.

7. The method of claim 1, wherein said linear tin (Sn) composition gradient minimizes abrupt strain changes, and reduces defect formation.

8. The method of claim 2, further comprising:
checking hardware and software of a molecular beam epitaxy (MBE) system operating the MBE chamber;
testing proportional-integral-derivative (PID) controller settings for effusion cell power supplies;
creating a beam equivalent pressure (BEP) versus temperature plot for tin (Sn);
fitting said beam equivalent pressure versus temperature plot with said equation to find coefficients ΔHₑ and P_{O} for said logarithmic-based algorithm;
selecting a linear grading rate for growing said germanium-tin (Ge₁₋ₓSnₓ) film; and
testing said germanium-tin (Ge₁₋ₓSnₓ) film using X-ray diffraction (XRD), secondary ion mass spectrometry (SIMS), and atomic force microscopy (AFM) to confirm said linear tin (Sn) composition gradient.

9. The method of claim 2, further comprising calibrating said tin (Sn) effusion cell temperature by measuring BEP of said tin (Sn) effusion cell at a plurality of temperatures to determine said molar heat of evaporation and said constant of integration.

10. A method for growing a linearly graded germanium-tin (Ge₁₋ₓSnₓ) film, said method comprising the steps of:
providing a substrate in a molecular beam epitaxy (MBE) chamber, by degassing and removing surface oxides under arsenic flux;
establishing a constant germanium (Ge) beam equivalent pressure (BEP), and a manipulator temperature gradient;
applying a logarithmic-based algorithm to dynamically control a tin (Sn) effusion cell temperature to achieve a linear increase in tin (Sn) beam equivalent pressure (BEP) over time; and
dynamically adjusting said tin (Sn) effusion cell temperature for growing a linear graded germanium-tin (Ge₁₋ₓSnₓ) film having a linear tin (Sn) composition gradient based on said logarithmic-based algorithm, while maintaining said manipulator temperature gradient.

11. The method of claim 10, wherein said logarithmic-based algorithm utilizes an equation:
$${T}_{Sn} = \frac{- Δ {H}_{e}}{R ln ( \frac{at + b}{{P}_{0}} )}$$
where T_{Sn} represents said tin (Sn) effusion cell temperature, R represents a gas constant, ΔHₑ represents a molar heat of evaporation, and P_{O} represents a constant of integration, t represents growth time, α represents a rate of BEP change across time, and b represents an offset variable that sets the starting BEP.

12. The method of claim 10, wherein said substrate comprises Gallium Arsenide (GaAs).

13. The method of claim 10, further comprising growing a buffer layer on said substrate prior to growing said linearly graded film.

14. The method of claim 10, wherein said Sn effusion cell comprises a dual-filament effusion cell with a base temperature and a tip temperature offset to stop the material from coalescing at the tip, or an electron-beam evaporation source with dynamically controlled beam current.

15. The method of claim 10, further comprising characterizing said GeSn using atomic force microscopy (AFM), X-ray diffraction (XRD), and secondary ion mass spectrometry (SIMS), Rutherford Backscattering Spectrometry (RBS), X-ray Photoelectron Spectroscopy (XPS) composition versus etching profiles for validating structural, and strain parameters and composition.

16. The method of claim 10, wherein said linear tin (Sn) composition gradient minimizes abrupt strain changes, and reduces defect formation.

17. The method of claim 11, further comprising:
checking hardware and software of a molecular beam epitaxy (MBE) system operating the MBE chamber;
testing proportional-integral-derivative (PID) controller settings for effusion cell power supplies;
creating a beam equivalent pressure (BEP) versus temperature plot for tin (Sn);
fitting said beam equivalent pressure versus temperature plot with said equation to find coefficients ΔHₑ and P_{O} for said logarithmic-based algorithm;
selecting a linear grading rate for growing said germanium-tin (Ge₁₋ₓSnₓ) film; and
testing said germanium-tin (Ge₁₋ₓSnₓ) film using X-ray diffraction (XRD), secondary ion mass spectrometry (SIMS), and atomic force microscopy (AFM) to confirm said linear tin (Sn) composition gradient.

18. The method of claim 11, further comprising calibrating said tin (Sn) effusion cell temperature by measuring BEP of said tin (Sn) effusion cell at a plurality of temperatures to determine said molar heat of evaporation and said constant of integration.

19. A molecular beam epitaxy (MBE) system for growing a linearly graded film, said MBE system comprising:
a molecular beam epitaxy chamber configured to maintain controlled conditions with substrate support;
at least one or more element or molecule source/sources configured to provide a constant beam equivalent pressure (BEP) or flow rate; and
at least one element or molecule or combination of more source/sources comprising of:
(i) a single-filament effusion cell comprising of one temperature control,
(ii) a dual-filament effusion cell comprising a base temperature and tip temperature controls,
(iii) an electron-beam evaporation source with dynamically controlled beam current, or
(iv) a gaseous delivery system with mass flow controllers (MFCs) or adjustable valves; and
a controller programmed with a time-dependent modulation algorithm, wherein said controller dynamically adjusts said other element or molecule source/sources to achieve a linear increase in beam equivalent pressure (BEP) or flow rate over time in order to grow a linearly graded film having a linear composition gradient.

20. The molecular beam epitaxy (MBE) system of claim 19, wherein said controller executes said time-dependent modulation algorithm based on an equation:
$${T}_{Sn} = \frac{- Δ {H}_{e}}{R ln ( \frac{at + b}{{P}_{0}} )}$$
where T_{Sn} represents said element or molecule source temperature or control parameter, R represents a gas constant, ΔHₑ represents a molar heat of evaporation, and P_{O} represents a constant of integration, t represents growth time, α represents a rate of BEP change across time, and b represents an offset variable that sets the starting BEP or flow rate.

21. A method for forming a film having an arbitrary target composition versus thickness profile comprising: defining the target composition profile; partitioning a total film thickness into N linearly compositionally changing contiguous segments with breakpoints; for each segment, determining a linear segment that locally approximates the target profile; during deposition, modulation at least one source-delivery parameter as a function of time so that an instantaneous composition slope within each segment corresponds to a selected segment slope; and maintaining continuity of composition at segment boundaries; whereby the deposited film exhibits a piecewise-linear composition profile that approximates the target profile, and wherein increasing N segments reduces an error metric relative to the target profile.

22. The method of claim 21, wherein deposition is performed by molecular beam epitaxy and the source-delivery parameter comprises electron-beam current or voltage control, effusion cell temperature control, or shutter timing for at least one constituent, modulated according to a time-dependent setpoint to realize the segment slopes.

23. The method of claim 21, wherein deposition is performed by chemical vapor deposition and the source-delivery parameter comprises mass-flow-controller setpoints, bubbler temperature or carrier-gas flow, or valve actuation for at least one precursor, modulated according to a time dependent setpoint to realize the segment slopes.

24. The method of claim 21, further comprising applying a smoothing or overlap window at one or more breakpoints to reduce abrupt setpoint transitions while preserving the target segment slopes within their respective intervals.

25. The method of claim 21, wherein N is selected such that a maximum deviation between the deposited composition profile and the target composition profile is less than a specified tolerance over the total film thickness.

26. The method of claim 21, wherein the target composition profile is non-monotonic and the set of segment slopes includes slopes of differing sign to realize composition regions that increase and decrease along the growth direction.

27. The method of claim 21, wherein the breakpoints and segment slopes are determined algorithmically by least-squares fitting, dynamic programming, or another optimization procedure that minimizes an error metric relative to the target composition profile.

28. A non-transitory computer-readable medium storing instructions that, when executed by a controller of a deposition system, cause the system to: receive a target composition profile; partition a total film thickness into a plurality of segments; compute linear segment parameters; generate time-dependent source setpoints to realize segment slopes during growth by molecular beam epitaxy or chemical vapor deposition type systems; and output control signals to source hardware so that the deposited film exhibits a piecewise-linear approximation of the target composition profile within a specified error tolerance.

29. The method of claim 21, wherein the target composition profile is an arbitrary single-valued function of film thickness, including monotonic or non-monotonic, continuous or piecewise-continuous (with a finite number of discontinuities), differentiable or non-differentiable, and is realized as a piecewise-linear approximation using a plurality of linear segments selected to achieve a specified error tolerance.

30. The method of claim 21, wherein the number of linear segments N is any positive integer, selected to achieve a user-specified error tolerance.

31. The method of claim 11, wherein the maximum deviation between the deposited composition and the target profile over each segment is less than a user-specified tolerance ε.

32. The method of claim 11, further comprising applying overlap or smoothing windows at segment boundaries to maintain substantial continuity while preserving the segment slopes.

33. A chemical vapor deposition (CVD) system for growing a linearly graded film, said CVD type system comprising:
a reaction chamber configured to maintain controlled conditions with substrate support;
at least one or more precursor lines configured to deliver precursors at a constant flow rate comprising of:
(v) a carrier gas flowing through a temperature-controlled bubbler; wherein flow control is achieved using a mass flow controller that modulates an internal valve to match the flow rate setpoint; and
(vi) manual or motor-actuated valves, operators can set flow control by precisely adjusting valve positions;
a gaseous precursor delivery system with mass flow controllers (MFCs) or manual or motor-actuated adjustable valves; and
at least one or more precursor lines configured to deliver the precursors controlled via time modulated flow rates comprising of:
(vii) a carrier gas flowing through a temperature-controlled bubbler; dynamically adjusting the carrier gas flow rate over time according to a predetermined ramp; wherein flow control is achieved using a mass flow controller that modulates an internal valve to match the flow rate setpoint; and wherein the adjustment results in a substantially linear incorporation of the second element along the thickness of the film; and
(viii) a gaseous precursor delivery system with mass flow controllers (MFCs) or adjustable valves; and
a controller programmed with a time-dependent modulation algorithm, wherein said controller dynamically adjusting the precursor or carrier gas flow rate or bubble temperature over time according to a predetermined ramp; wherein flow control is achieved using a mass flow controller that modulates an internal valve to match the flow rate setpoint; and wherein the adjustment results in a substantially linear incorporation of the second element along the thickness of the film.

34. The method of claim 33, wherein the dynamic adjustment of precursor flow rate or carrier gas flow rate is implemented using a programmable mass flow controller.

35. The method of claim 34, wherein the flow ramp is derived from a calibration equation to fit curve mapping precursor flow rate to atomic composition characterization plots derived from growing an unknown gradient with known varied precursor flow ramp rate or carrier gas flow ramp rate or alternatively bubble temperature parameters.
